(19) United States
(12) Patent Application Publication
(10) Pub. No.: US 2016/0260585 A1
(43) Pub. Date: Sep. 8, 2016

(54) MULTI-GRID ASSEMBLY IN PLASMA SOURCE SYSTEM AND METHODS FOR IMPROVING SAME

(71) Applicant: Hariharakeshava Sarpangala Hegde, Fremont, CA (US)

(72) Inventor: Hariharakeshava Sarpangala Hegde, Fremont, CA (US)

(21) Appl. No.: 15/072,066

(22) Filed: Mar. 16, 2016

Related U.S. Application Data
(63) Continuation of application No. 13/180,456, filed on Jul. 11, 2011, now abandoned.

(51) Int. Cl. H01J 37/32

(52) U.S. Cl. CPC H01J 37/32422; H01J 37/32669; H01J 2237/3343

(57) ABSTRACT

A plasma processing system with a multi-grid arrangement is provided. The system includes a plurality of grids, which includes at least a beam grid, a ground grid and a suppressor grid. The beam grid is positioned facing a plasma producing area, wherein the beam grid having similar electrical potential as a plasma. The ground grid is positioned to face a substrate during substrate processing and is configured to be electrically grounded. The suppressor grid is positioned between the beam grid and the ground grid and is configured to be negatively charged. The plurality of grids further includes a set of grid mounting posts configured for at least one of stabilizing said multi-grid arrangement, spatially separating adjacent grids, and fastening the plurality of grids into the multi-grid arrangement.

### FIELD OF THE INVENTION

Embodiments relate generally to a grid assembly for an ion beam apparatus.

### BACKGROUND

In a typical multi-grid ion beam system, plasma is generated by a suitable plasma source using, for example, RF energy in an inductive or capacitive manner and is employed to deposit materials on a wafer or to etch materials therefrom. Between the plasma source and the wafer, there typically exists a multi-grid assembly, which functions to extract ions from the plasma and to cause the ions to be emitted toward the wafer in a collimated fashion. Generally speaking, a typical multi-grid assembly may comprise at least two and typically three separate grids. Each grid has a plurality of holes disposed therein (up to thousands of holes) designed to allow ions to traverse the grid. When the grids are assembled in a multi-grid assembly, the holes are aligned to form through passages to allow ions to traverse from the plasma through the holes in the multigrid assembly toward the wafer.

Generally speaking, the grids are electrically insulated from one another and kept apart spatially. The grid that is closest to the plasma is typically known as a beam grid and is typically at the same electrical potential as the plasma. On the other hand, the grid that faces the wafer is typically known as the ground grid and is electrically grounded. In between the beam grid and the ground grid, there exists a suppressor grid that is negatively charged to attract ions out of the plasma. There may exist other grids and other components but these three grids are typically found in a typical multi-grid assembly.

As feature sizes on the wafer become smaller and smaller and deposition or etch requirements become more critical for these small feature size components on the wafer, it is more important than ever to more tightly control the deposition or etch process. One of the parameters that needs to be controlled is deposition or etch uniformity. In the context of the present invention, uniformity refers to the ability to deposit or etch material uniformly across the wafer such that there is a low degree of variation in the deposition or etch rate from the center of the wafer to the edge of the wafer. This invention relates to techniques to improve uniformity by modifying the multi-grid assembly such that the grid thickness, the grid-to-grid spacing, and the center-to-edge thickness of the multi-grid assembly can be controlled to improve uniformity.

### SUMMARY

An example of an apparatus embodiment includes a multi-grid assembly for a plasma processing system. The multi-grid assembly includes three grids. The three grids include a beam grid at a same electrical potential as a plasma during plasma processing; a ground grid electrically grounded during plasma processing; and a suppressor grid disposed between the beam grid and the ground grid, the suppressor grid negatively charged during plasma processing. The example of a multi-grid assembly further includes a grid mounting post formed as a solid stud without apertures; a plurality of the grid mounting post coupling the suppressor grid to the beam grid and the ground grid, the plurality of the grid mounting post positioned near an edge of the beam grid; and an additional plurality of the grid mounting post coupling the suppressor grid to the beam grid and the ground grid, the additional plurality of the grid mounting post positioned in a central portion of the beam grid, wherein, for the plurality and the additional plurality of the grid mounting post, a first spacer surrounds each of the grid mounting post between the beam grid and the suppressor grid, a second spacer surrounds each of the grid mounting post between the suppressor grid and the ground grid, and each of the grid mounting post contacts the suppressor grid without contacting either of the beam grid or the ground grid.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, in accordance with an embodiment of the invention, an inventive multi-grid assembly wherein the beam grid is made thicker in order to improve multi-grid assembly stability and multi-grid assembly lifetime.

FIG. 2 shows, in accordance with an embodiment of the invention, another view of the improved multi-grid assembly.

FIG. 3 is a cut-away drawing of an example inventive multi-grid assembly mounted to the hardware of the plasma chamber.

FIG. 4 shows a modified grid mounting post arrangement in accordance with one or more embodiments of the invention.

FIG. 5 shows, in accordance with an embodiment of the invention, a method to alternatively or additionally modulate the thickness between grids from the center to the edge of the multi-grid assembly.

FIG. 6 shows in greater detail, in an example embodiment, shim sheets to modulate the multi-b-rid assembly thickness.

FIG. 7 shows an example plasma source with an example innovative permanent magnet arrangement.

FIG. 8 shows in greater detail, in accordance with an embodiment, the permanent magnet assembly.

FIG. 9 shows another view of an embodiment of the permanent magnet assembly.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, optomagnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to methods and apparatuses to improve the stability and lifetime of the multi-grid assembly. In an embodiment, it is discovered by the inventor that when the beam grid is made thicker than either the suppressor grid or the ground grid, the overall stability and the lifetime of the multi-grid assembly is significantly enhanced with little reduction in key performance parameters of the ion source. One consideration is a thicker beam grid may increase the beam-grid-to-suppressor-grid spacing with a slight corresponding loss in etch rate. However, this can be balanced against the increased structural stability and lifetime of the multi-grid assembly since the beam grid tends to be the grid that faces the plasma and is subjected to the most environmental stress and can benefit the most from increased thickness/strength. Since the beam grid is at the same potential as the plasma, increasing the thickness of the beam grid tends to have low or negligible impact on the electrical characteristics of the plasma.

One or more embodiments of the invention also relate to improvement to etch uniformity and radial etch profile by modulating the center-to-edge thickness of the multi-grid assembly. In an embodiment, the grid mounting posts that are used to stabilize and spatially separate as well as fasten together the plurality of grids in the multi-grid assembly are configured such that the thickness of the multi-grid assembly varies from center to edge.

For example, some multi-grid assembly may be made thicker at the center relative to the edge by configuring the center grid mounting posts such that the grids at the center portion of the multi-grid assembly are more spatially separated from one another than at the edge portion of the grids. In other embodiments, the multi-grid assembly may be thinner at the center than at the edge by configuring the grid mounting posts to compress the grids together at the center portion to a greater degree than at the edge portion. Still in other embodiments, the grid mounting posts may be used to locally control the thickness of the multi-grid assembly so that the assembly may have complex shapes that may include localized maximum and minimum instead of a simple planar multi-grid assembly shape.

One or more embodiments of the invention also improve the radial etch profile and uniformity by using an innovative permanent magnet assembly to influence the plasma that is emitted from the plasma source.

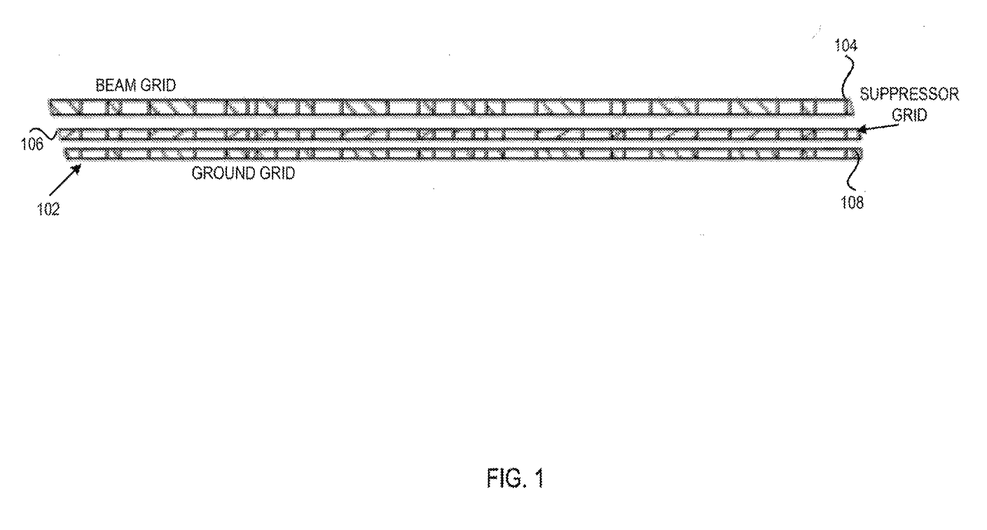

In the following discussion, an etch application is employed as an example although embodiments of the invention apply equally to deposition applications. FIG. 1 shows, in accordance with an embodiment of the invention, an inventive multi-grid assembly wherein the beam grid is made thicker than one or both of the suppressor grid and the ground grid in order to improve multi-grid assembly stability and multi-grid assembly lifetime.

With reference to FIG. 1, there is shown a portion of a multi-grid assembly 102, which includes a beam grid 104, a suppressor grid 106 and a ground grid 108. As can be seen in FIG. 1, each of beam grid 104, suppressor grid 106, and ground grid 108 have therein a plurality of holes (up to hundreds or thousands of holes) sized to allow ions to traverse through the multi-grid assembly from the plasma toward the wafer. When assembled together in a multi-grid assembly, the holes are aligned.

In FIG. 1, beam grid 104 faces the plasma (which is toward the top of the figure in FIG. 1) whereas ground grid 108 faces the wafer (which is toward the bottom of FIG. 1). By making beam grid 104 substantially thicker than either suppressor grid 106 or ground grid 108, the beam grid can last longer in the plasma-intensive environment. Furthermore, suppressor grid 106 and ground grid 108 are deliberately not made thicker (as opposed to the thicker beam grid 104) to minimize impact on performance. In so doing, it has been found that the structural integrity of the resultant multi-grid assembly and grid lifetime are substantially enhanced with substantially no loss of performance or with only insubstantial loss in performance.

In some sensitive applications, increasing the thickness of beam grid 104 may cause a slight decrease in the available etch rate since a thicker beam grid 104 means that the effective beam-grid-to-suppressor-grid spacing is increased by half the thickness of the increase thickness in the beam grid and therefore there is a corresponding loss in the etch rate. However, even in these sensitive applications, it is possible that the loss in etch rate may be compensated for by increasing the power or changing other parameters in order to take advantage of the improved multi-grid assembly lifetime and structural stability that is derived from the relative increase in beam grid thickness. In other applications, it may be deemed an acceptable trade off to have a slightly reduced etch rate in exchange for increased multi-grid assembly stability and lifetime.

Since beam grid 104 is at the same potential as the plasma, the inventor herein realizes that increasing the beam grid thickness relative to the thickness of the other grids would result in very little or substantially no increase in contamination due to beam grid material etching.

Embodiments of the invention also relate to improvements in etch uniformity and radial etch profile by modulating the thickness of the multi-grid assembly from center-to-edge. If the multi-grid assembly is thicker at the center portion of the multigrid assembly, for example, the etch rate at the center portion of the wafer would be less than at the edge portion of the wafer. Conversely, when the multi-grid assembly is thinner at the center portion relative to the edge portion, the etch rate at the center portion is higher than at the edge portion. By modulating the thickness of the multi-grid assembly from center-to-edge, it is possible to tune the radial uniformity and radial etch profile across the wafer.

It is observed by the inventor that in shaping the thickness of the multi-grid assembly from center-to-edge, the separation between the beam grid and the suppressor grid tends to have a greater effect, sometime a much greater effect, than the thickness variation between the ground grid and the suppressor grid. In one or more embodiments, the spatial separation between the beam grid and the suppressor grid is increased while maintaining the spatial separation between the suppressor grid and the ground grid unchanged. In one or more other embodiments, the spatial separation between the beam grid and the suppressor grid remains unchanged while the spatial separation between the suppressor grid and the ground grid is increased. In one or more embodiments, the spatial separation between the beam grid and the suppressor grid is increased and the spatial separation between the suppressor grid and the ground grid is also increased.

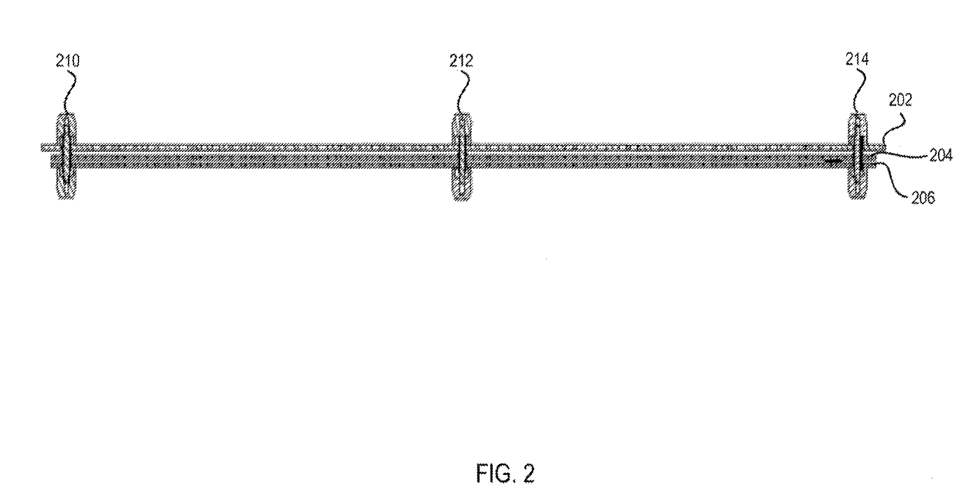

In one or more embodiments, the grid mounting posts are advantageously employed or leveraged to create the modulation in multi-grid assembly thickness from center-to-edge. FIG. 2 shows, in accordance with an embodiment of the invention, the improved multi-grid assembly wherein beam grid 202 is thicker than either suppressor grid 204 or ground grid 206. In this example, there are shown three grid mounting posts 210, 212 and 214. Grid mounting post 212 may cause the grids (such as beam grid 202, suppressor grid 204 and/or ground grid 206) to be spatially separated to a greater degree than is done by grid mounting post 210 or grid mounting post 214. In this manner, the entire multi-grid assembly essentially bows or bulges outward at the center portion, in effect creating a thicker multi-grid assembly at the center portion relative to the edge portion. In this case, the etch rate will be slower at the center since the multi-grid assembly appears to the plasma to be thicker at the center portion than at the edge portion.

Conversely, grid mounting post 210 (and/or grid mounting post 214) may cause the grids 202, 204 and 206 to be spatially separated to a greater degree than is separated by grid mounting post 212. In this manner, the multi-grid assembly is thinner at the center portion (since grid mounting post 212 keeps the grids closer together at the center portion compared to grid mounting post 210 and/or grid mounting post 214, which keep(s) the grids further apart at the edge portion). Consequently, the etch rate at the center portion of the wafer tends to be faster than at the edge portion of the wafer since the multi-grid assembly appears to be thicker to the plasma at the edge portion than at the center portion.

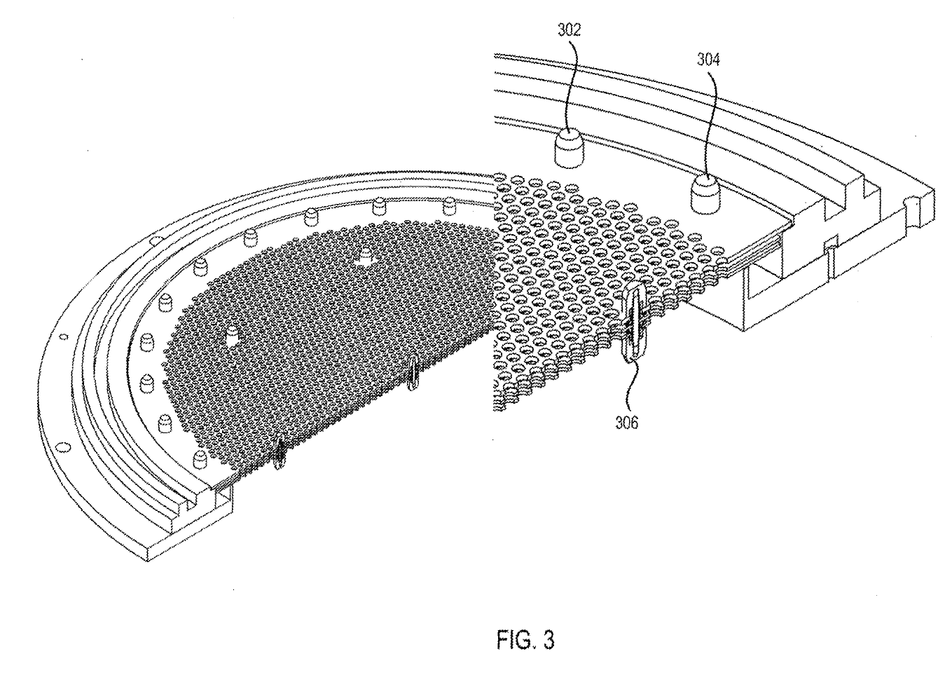

FIG. 3 is a cut-away drawing of an example inventive multi-grid assembly mounted to the hardware of the plasma chamber. Again, multi-grid assembly 302 comprises three separate grids. These grids are mechanically coupled together and kept spatially apart by a plurality of grid mounting posts of which grid mounting posts 302, 304 and 306 are shown. The details of the grid mounting posts and the modification(s) thereto to achieve the aforementioned modulation of multi-grid assembly thickness from center-to-edge of the multi-grid assembly will be discussed later herein.

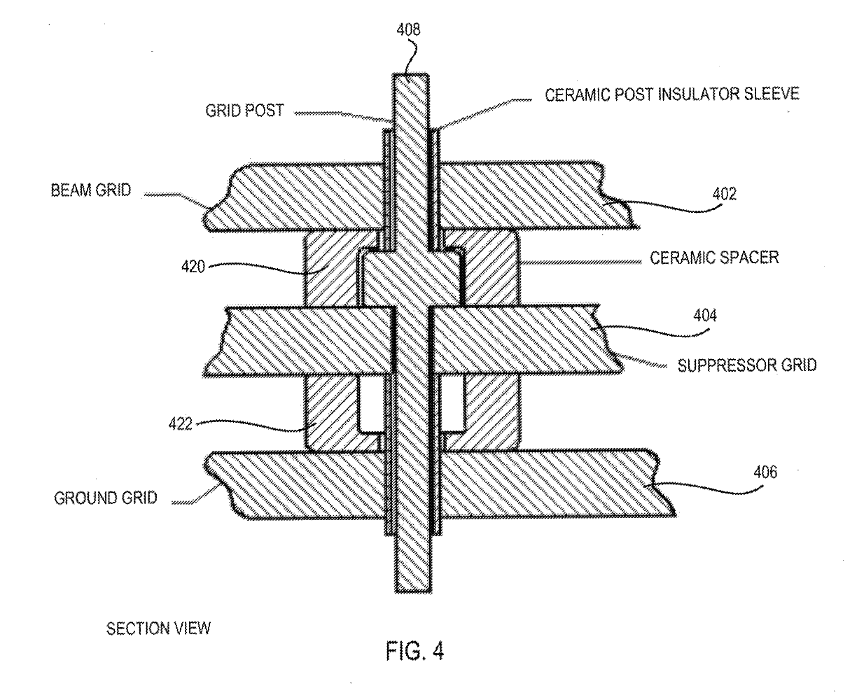

FIG. 4 shows a modified grid mounting post arrangement in accordance with one or more embodiments of the invention. In this example, ceramic spacers of varying thicknesses are employed and are dimensioned to separate the grids at different spacings from center-to-edge, thereby creating the aforementioned modulation and grid thickness variation from center-to-edge in order to tune the radial uniformity and radial etch profile. In the example of FIG. 4, there is shown beam grid 402, suppressor grid 404 and ground grid 406. Stud 408 is shown disposed or inserted through beam grid 402, suppressor 404, and ground grid 406. The stud caps are omitted from FIG. 4 to simplify the illustration.

In between adjacent grids, there exist insulating spacers of which insulating spacer 420 and insulating spacer 422 are shown. Each insulating spacer may be thought of as a substantially cylindrical object having a thickness dimensioned to keep adjacent grids spaced apart at a predefined thickness. Generally speaking, the insulating spacers may be made of a suitable material such as ceramic. To keep the individual grids electrically insulated from one another, there may exist one or more insulating sleeves to keep stud 408 electrically insulated from its grids, thereby allowing beam grid 402, suppressor grid 404 and ground grid 406 to be electrically isolated from one another. In one or more embodiments, the ceramic spacers may be provided with special features (such as grooves) to reduce the risk of inadvertent electrical conduction due to the formation of a conductive film from deposited conductive material coming from wafer processing, thereby ensuring continued electrical insulation between adjacent grids.

In the example of FIG. 4, insulating spacer 420 may be made slightly thicker than insulating spacer 422 (or vice versa) to slightly increase or alter the separation between beam grid 402 and suppressor grid 404 at the center portion of the multi-grid assembly. In this example, the thickness of insulating spacer 420 may be kept the same for the grid mounting posts at the edge of the multi-grid assembly so that the increase in multi-grid assembly thickness, which is caused by the greater separation between beam grid 402 and suppressor grid 404, is achieved only at the center portion of the multi-grid assembly.

Another example, both insulating spacer 420 and insulating 422 may be made thicker for the grid mounting posts at the center portion relative to the insulating spacers at the edge portion to achieve a greater bulging effect for the multi-grid assembly at the center portion relative to the edge portion. In yet another example, insulating spacer 420 and insulating spacer 422 may be made thinner for the grid mounting posts at the center portion of the multi-grid assembly relative to the insulating spacers for the grid mounting post(s) at the edge of the multi-grid assembly to achieve a concave effect for the entire multi-grid assembly. In this manner, the radial uniformity and radial etch profile on the wafer may be tuned by varying the shape of the multi-grid assembly from center to edge.

In one embodiment of the grid-to-grid spacing modulation for wafer etch unifomlity modulation, the beam-to-suppressor spacing may be modulated while leaving the suppressor-to-ground spacing uniform throughout the assembly. Most of the benefit to unifomlity modulation is gained through the beam-suppressor spacing modulation.

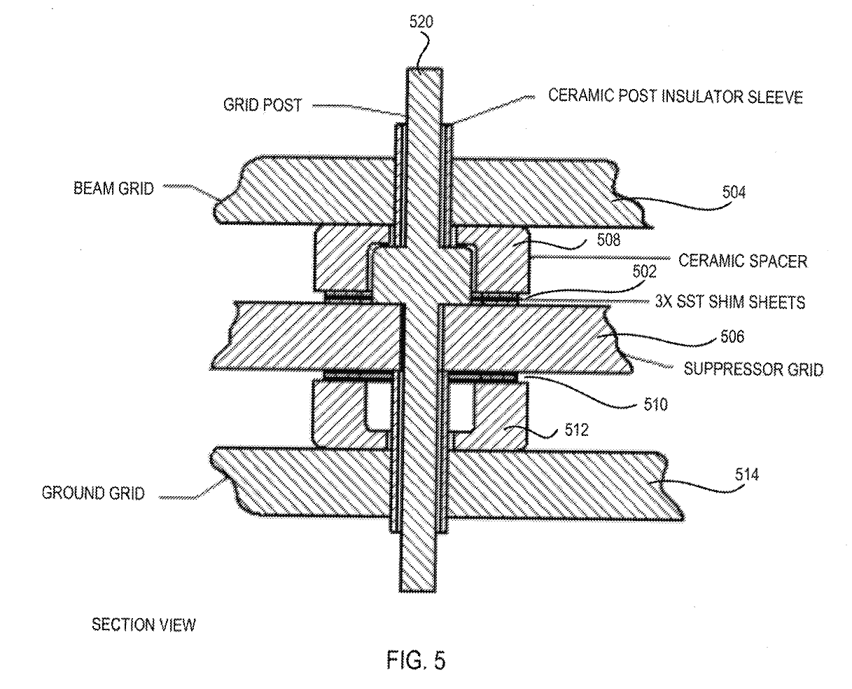

FIG. 5 shows, in accordance with an embodiment of the invention, a method to alternatively or additionally modulate the thickness between grids from the center to the edge of the multi-grid assembly in order to tune the radial uniformity and radial etch profile across the wafer. In the example of FIG. 5, a generic insulating spacer of a predefined thickness may be employed to reduce the inventory cost of keeping or stocking insulating spacers of various thicknesses. In this example, shim sheets (e.g., in the shape of washers) may be inserted under and/or above one or more insulating spacers in order to increase the spatial separation between adjacent grids. In this example, three shim sheets are inserted at position 502 below spacer 508 to increase the spatial separation between beam grid 504 and suppressor grid 506 at position 502. In a similar manner, shim sheets may be inserted at position 510 above ceramic spacer 512 in order to increase the spatial separation between suppressor grid 506 and ground grid 514 at position 510.

Note that the shim sheets may advantageously be used to increase the spatial separation between any pair of adjacent grids (such as between the beam grid and the suppressor grid) at any specific location in the multi-grid assembly. Also, note that the shim sheet may be inserted either under or above a particular insulating spacer as desired. The shim sheets or washers may be made of any suitable material, including for example ceramic or stainless steel. Since stud 520 is electrically insulated from the various grids in one or more embodiments, the shim sheets may be made of a conductive material if desired without violating the requirement that the various grids be electrically insulated from one another.

In one or more embodiments, a shim sheet thickness may be from between about 0.0005 to about 0.005 inch, for example. Different thicknesses may be achieved by using a stack of multiple shim sheets, or a single shim sheet of a desired thickness may be employed. In a preferred embodiment, it is found by the inventors that the variation in grid-to-grid spacing should be kept to about 6% or less of the average grid-to-grid spacing so as not to unduly change other key grid characteristics such as beam diversions and beam steering. In other embodiments where such characteristics may be somewhat compromised in the interest of greater etch uniformity/profile control, variation in grid-to-grid spacing greater than 6% of the average grid-to-grid spacing may be employed if desired.

By inserting the shim sheet(s) either above or below the insulating spacer in between adjacent grids at specific locations in the multi-grid assembly, it is possible to introduce local variations in the spatial separation between adjacent grids, thereby achieving variations in multi-grid assembly thickness from center-to-edge or azimuthally or in any desired complex shape in order to tune the radial uniformity and radial etch profile radially (from center to edge) or azimuthally.

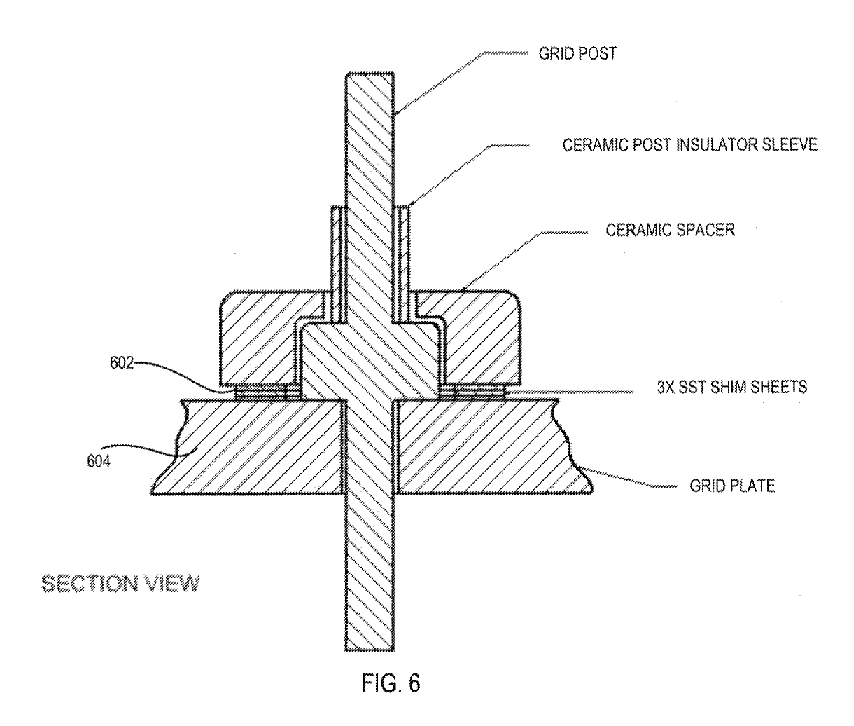

FIG. 6 shows in greater detail, in an example embodiment, three shim sheets inserted at position 602 above suppressor grid 604 in order to increase the grid-to-grid separation between the suppressor grid and the beam grid at position 602. By varying the number and/or thickness of shim sheets from center-to-edge or azimuthally, it is possible to tune the thickness of the entire multi-grid assembly to achieve the aforementioned radial uniformity and radial etch profile tuning.

Embodiments of the invention also relate to an alternative magnet ring arrangement to tune the radial etch uniformity and radial etch profile. In accordance with one or more embodiments of the invention, permanent magnets instead of electromagnets may be employed to form a ring around the outside of the plasma chamber. These magnet rings may be mounted on the atmospheric side to simplify installation and maintenance. The permanent magnets are oriented so that there is north-south orientation of the magnets along the axis of the plasma source. The magnet field penetrates the plasma and modifies the plasma density, allowing the radial etch uniformity or the radial etch profile to be modified.

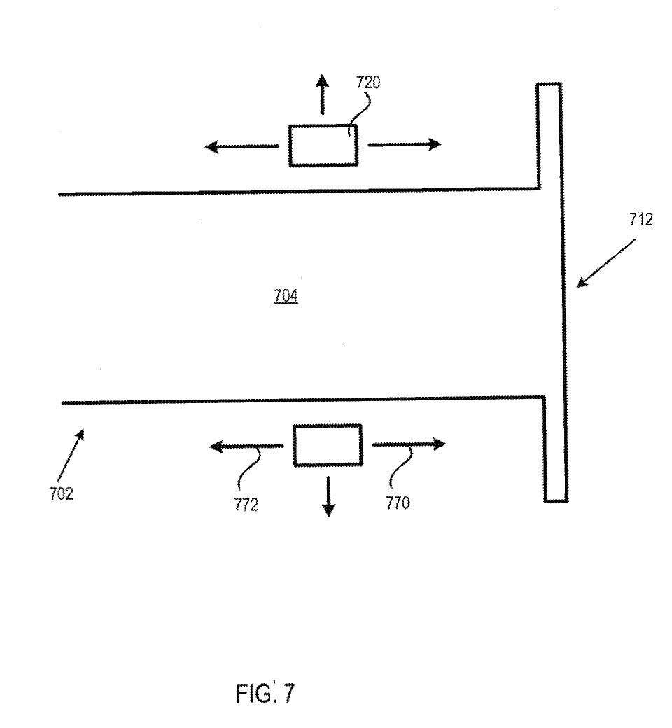

In one or more embodiments, magnet rings are formed using a set of bar magnets with their north poles placed on a soft steel ring, and another set of bar magnets with their south poles also placed on a soft steel ring. The steel rings are placed next to each other as shown in FIG. 7, for example. The steel rings may comprise several sections of a circular-shaped ring instead of being a single unit, for example. In other words, the soft steel cores in one or more embodiments may be broken into multiple rings of equal diameters or may be merged into a single ring or may be formed of ring segments.

With reference to FIG. 7, there is shown plasma source 702, which is configured to form a plasma within plasma chamber 704. The plasma may be formed by inductive or capacitive coupling, for example. If inductive coupling is employed, a suitable antenna may be employed, for example.

The plasma generated within plasma chamber 704 is used to perform etch on a wafer (not shown in FIG. 7) located some distance away from source opening 712. There may be disposed one or more multi-grid assembly/assemblies in between plasma source 702 and the wafer as discussed earlier. A permanent magnet assembly 720 is shown disposed around the outer periphery of plasma chamber 704 such that permanent magnet assembly 720 is disposed on the atmospheric side.

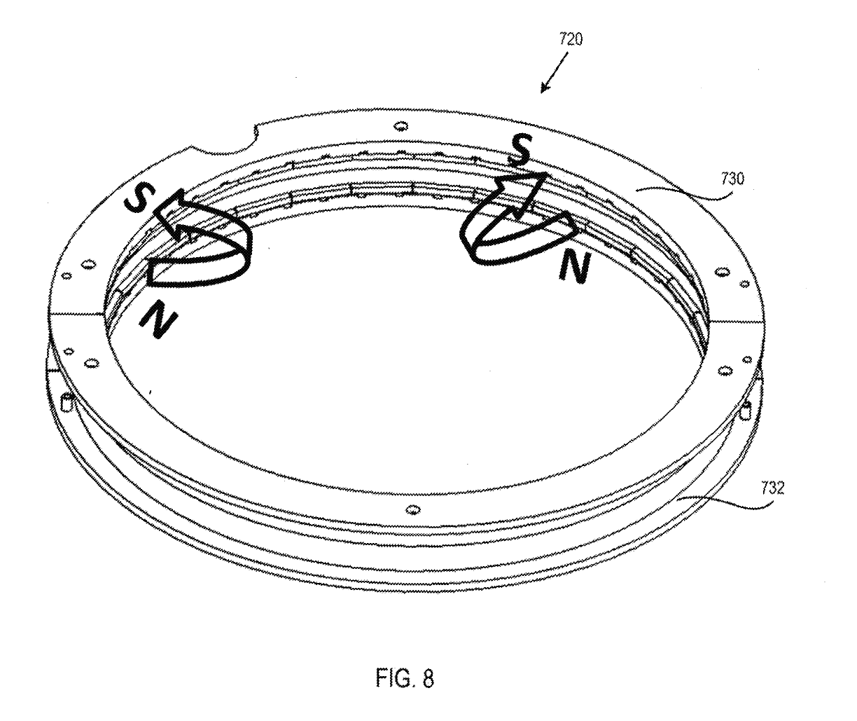

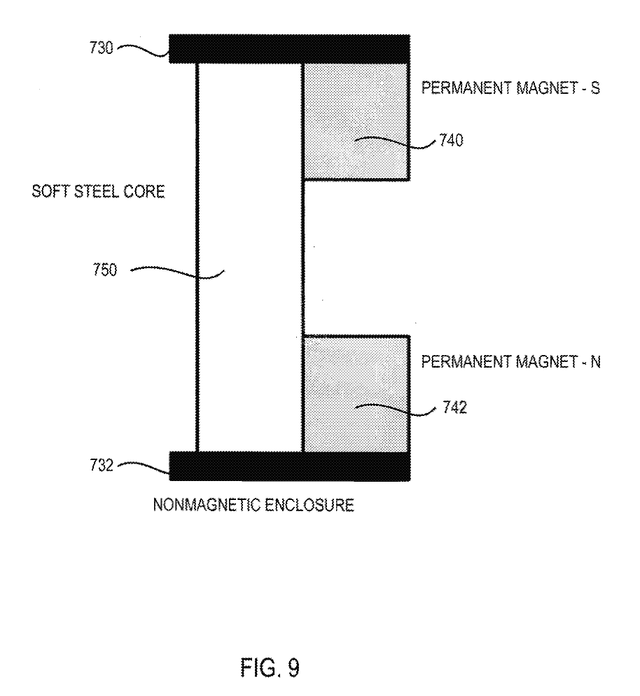

FIG. 8 shows in greater detail permanent magnet assembly 720 in accordance with one or more embodiments of the invention. Permanent magnet assembly 720 includes claddings 730 and 732 (also shown in FIG. 9). Cladding 730 and cladding 732 are typically made of non-magnetic material(s) and are employed to mount permanent magnets 740 and 742 of FIG. 9. Permanent magnet 740 represents the south pole whereas permanent magnet 742 represents the north pole in the example of FIG. 9. The permanent magnets 740 and permanent magnet 742 may be spaced apart by a soft steel core or a spacer made out of a suitable material 750.

In use, the plasma density in the radial direction in plasma chamber 704 and/or at source opening 712 may be tuned by moving permanent magnet assembly 720 along the direction of the source axis (in the direction of arrows 770 and 772 of FIG. 7 for example). Further, the plasma density may also be tuned by changing the strength of the permanent magnets. Tuning may also be performed by changing the distance between the north and south poles such that the north and south poles may be moved closer together or further apart. Other tuning knobs may include changing the strength of the magnets, or changing the diameter of the permanent magnet ring or changing the size of the permanent magnet ring or changing the inner diameter of the permanent magnet ring relative to the outer diameter of the plasma chamber.

For a particular application, the optimal plasma density in the radial direction may be determined empirically in advance and tuned using a permanent magnet assembly.

As can be appreciated from the foregoing, advantages of the invention include a longer lifetime for the multi-grid assembly and improved structural rigidity by increasing the thickness of the beam grid without impacting key parameters of the plasma process. One or more embodiments of the invention can also modulate the radial etch/deposition profile or radial etch/deposition uniformity by changing the thickness of the multi-grid assembly at the center relative to the edge of the multi-grid assembly. By providing an inexpensive and highly configurable permanent magnet assembly, the radial etch profile and etch uniformity and/or plasma density in the radial direction may also be tuned.

While this invention has been described in terms of several preferred embodiments, there are alterations, permutations, and equivalents, which fall within the scope of this invention. It should also be noted that there are many alternative ways of implementing the methods and apparatuses of the present invention. Although various examples are provided herein, it is intended that these examples be illustrative and not limiting with respect to the invention. Also, the title is provided herein for convenience and should not be used to construe the scope of the claims herein. If the term “set” is employed herein, such term is intended to have its commonly understood mathematical meaning to cover zero, one, or more than one member.

What is claimed is:

1. A multi-grid assembly for a plasma processing system, comprising:
three grids, comprising:
a beam grid at a same electrical potential as a plasma during plasma processing;
a ground grid electrically grounded during plasma processing; and
a suppressor grid disposed between said beam grid and said ground grid, said suppressor grid negatively charged during plasma processing;
a grid mounting post formed as a solid stud without apertures;
a plurality of said grid mounting post coupling said suppressor grid to said beam grid and said ground grid, said plurality of said grid mounting post positioned near an edge of said beam grid; and
an additional plurality of said grid mounting post coupling said suppressor grid to said beam grid and said ground grid, said additional plurality of said grid mounting post positioned in a central portion of said beam grid,
wherein, for said plurality and said additional plurality of said grid mounting post, a first spacer surrounds each of said grid mounting post between said beam grid and said suppressor grid, a second spacer surrounds each of said grid mounting post between said suppressor grid and said ground grid, and each of said grid mounting post contacts said suppressor grid without contacting either of said beam grid or said ground grid.

2. The multi-grid assembly of claim 1, wherein a center-to-edge thickness of said multi-grid assembly is adjusted to control at least one of etch uniformity and radial etch.

3. The multi-grid assembly of claim 2, wherein a spatial separation between two adjacent grids is wider at a grid mounting post in a center portion of said multi-grid assembly than at a grid mounting post near an edge of said multi-grid assembly.

4. The plasma processing system of claim 2 wherein a center portion of said multigrid arrangement is thinner relative to an edge portion of said multi-grid arrangement such that spatial separation between two adjacent grids is narrower at a central grid mounting post than at said edge portion of said multi-grid arrangement.

5. The multi-grid assembly of claim 2, wherein a first spatial separation between a first outer grid and said suppressor grid is greater than a second spatial separation between a second outer grid and said suppressor grid.

6. The multi-grid assembly of claim 5, wherein said first outer grid is said beam grid and said second outer grid is said ground grid.

7. The multi-grid assembly of claim 5, wherein said first outer grid is said ground grid and said second outer grid is said beam grid.

8. The multi-grid assembly of claim 1, wherein said first spacer and said second spacer are made from ceramic.

9. The multi-grid assembly of claim 1, further including a shim interposed between said first spacer and said suppressor grid for at least one of said grid mounting post positioned in said central portion of said beam grid.

10. The multi-grid assembly of claim 9, wherein said shim is made from ceramic.

11. The multi-grid assembly of claim 9, wherein said shim is made from stainless steel.

12. The multi-grid assembly of claim 1, wherein said beam grid is thicker than at least one of said suppressor grid and said ground grid.

13. The multi-grid assembly of claim 1, further comprising a shim interposed between said second spacer and said suppressor grid for at least one of said grid mounting post positioned in said central portion of said beam grid.

14. The multi-grid assembly of claim 1, further comprising an insulator sleeve interposed between said grid mounting post and said beam grid.

15. The multi-grid assembly of claim 14, wherein said insulator sleeve is interposed between said grid mounting post and said first spacer.

16. The multi-grid assembly of claim 1, wherein a thickness of said first spacer is greater than a thickness of said second spacer.
